(19) United States
(12) Patent Application Publication
(10) Pub. No.: US 2003/0179892 A1
(43) Pub. Date: Sep. 25, 2003

(54) System and method for an improved configuration for stereo headphone amplifiers

(76) Inventor: Kim Nordtorp Madsen, Skovlunde (DK)

Correspondence Address: TEXAS INSTRUMENTS INCORPORATED, P O BOX 655474, M/S 3999, DALLAS, TX, 75265

(21) Appl. No.: 10/105,147

(22) Filed: Mar. 25, 2002

(51) Int. Cl. H03F 21/00

(52) U.S. Cl. 381/120; 381/121

(57) ABSTRACT

Systems and methods for reducing crosstalk in power amplifiers driving low impedance loads are provided. A low impedance power amplifier includes a first power amplifier and a second power amplifier. The first power amplifier amplifies a first signal and the second power amplifier amplifies a second signal. A mid-rail component is connected to the first power amplifier and the second differential amplifier in order to provide a DC bias for the amplified signals. The first and second differential amplifiers drive a low impedance load (e.g., headphone speakers). A common ground of a low impedance load is connected to a mid-rail component that compensates for mid-rail component variations in the amplified signals facilitating the reduction of crosstalk.

### TECHNICAL FIELD

The present invention relates to audio applications and in particular to systems and methods for an improved configuration for a low impedance power amplifier.

### BACKGROUND OF INVENTION

Audio amplifiers receive an incoming audio signal and output an audio signal with sufficient power to drive a load, such as headphone speakers. As the use of small, portable audio devices has increased, the demand for small, powerful audio amplifiers has also increased. Thus, the size of and power used by power amplifiers are of increasing relevance.

The load driven by audio amplifiers employed in small devices is typically a small load, such as about 4 ohms to about 600 ohms. Additionally, stereo audio amplifiers typically receive a left signal and a right signal and drive a left load (e.g., left headphone speaker) and a right load (e.g., right headphone speaker). One conventional audio amplifier 100 is illustrated in FIG. 1. The amplifier 100 is operative to receive a left signal 104 and a right signal 102. The left signal 104 and the right signal 102 are illustrated as voltage sources. The left signal 104 and the right signal 102 are applied to the differential inputs of a left amplifier 108 and a right amplifier 106, respectively, via resistors R1 and R2. The positive input of the left amplifier 108 and the positive input of the right amplifier 106 are connected to a mid-rail component 114. The mid-rail component 114 provides half of a supply voltage. The mid-rail component 114 typically comprises a voltage divider circuit, however it is represented as a battery (V_{DD}/2) for illustrative purposes. Capacitors C1 and C2 are connected to the right amplifier 106 and the left amplifier 108, respectively. Left load 110 is connected to the capacitor C2 and right load 112 is connected to the capacitor C1. The left load 110 and the right load 112 are then connected to a ground, which is the electrical or circuit ground for the audio amplifier 100.

The capacitors C1 and C2 protect loads, such as headphones, from likely damage due to DC current flow (e.g., through a voice coil of a speaker). Thus, the capacitors C1 and C2 are coupling capacitors that block a DC offset voltage from reaching the load. Such capacitors can be quite large (approximately 33 micro-farads to 1000 micro-farads), thus the capacitors C1 and C2 are generally expensive, heavy, and occupy a large amount of circuit board space. The coupling capacitors also have the drawback of limiting the low-frequency performance of the audio amplifier 100.

Eq. 1, depicted below, is a transfer function for an output portion 120 of the audio amplifier. The coupling capacitors limit the frequency response of the audio amplifier I100. This performance limiting effect (f_{c}) is due to the high pass filter network created with the load impedance (R_{L}) and the coupling capacitance (C_{c}) of the output portion 120. The relationship is depicted in Eq. 1:

$${f}_{c} = \frac{1}{2 π {R}_{L} {C}_{c}} \qquad Eq . 1$$

Thus, for a 330 micro-farad coupling capacitor (C_{c}) and a 32 ohm speaker load (R_{L}), frequencies below 150 Hz are attenuated. Since the load impedance (R_{L}) is typically quite small, larger values of C_{c} are required to deliver low frequencies to the load. TABLE 1, depicted below, summarizes the frequency response characteristics of such a configuration with a C_{C} of 330 μF and loads of 4 ohms, 8 ohms, 16 ohms, and 32 ohms.

TABLE 1

| R_{L} | C_{C} | LOWEST FREQUENCY |
|---|---|---|
| 4 ohms | 330 μF | 120 Hz |
| 8 ohms | 330 μF | 60 Hz |
| 16 ohms | 330 μF | 30 Hz |
| 32 ohms | 330 μF | 15 Hz |
| 150 ohms | 330 μF | 8 Hz |
| 600 ohms | 330 μF | 4 Hz |

Thus, it is appreciated that much of the bass response is attenuated for the 4 ohm load with the 600 ohm load having the best bass response of Table 1.

Another conventional audio amplifier 200 is illustrated in FIG. 2. The amplifier 200 is operative to receive a left signal 204 and a right signal 202 of an audio signal. The left signal 204 and the right signal 202 are illustrated as voltage sources. The left signal 204 and the right signal 202 are applied to the differential inputs of a left amplifier 208 and a right amplifier 206, respectively, via resistors R3 and R4. The positive input of the left amplifier 208 and the positive input of the right amplifier 206 are connected to a mid-rail component 214, which provides half of a supply voltage. Left load 210 is connected to the left amplifier 208 and right load 212 is connected to the right amplifier 206. The left load 210 and the right load 212 are then connected to a ground via capacitor C_{OUT}.

Similar to the capacitors of FIG. 1, C_{OUT} protects loads, such as headphones, from likely damage due to DC current flow through the voice coil. Thus, the capacitor C_{OUT} is a coupling capacitor that blocks a DC offset voltage from reaching the load. The system 200 can drive a load as well as the audio power amplifier system 100 of FIG. 1, but utilizes only a single capacitor C_{OUT} connected to the load. Thus, compared with system 100 of FIG. 1, the system 200 requires one less capacitor, thereby providing a lower parts count, smaller layout area, increased reliability and reduced costs. However, the system 200 does generally have increased crosstalk between the two signals, the left signal 204 and the right signal 202. Crosstalk is interference or attenuation of a signal due to interference from another signal.

Eq. 2 depicts the final transfer function of the circuit.

$$\frac{{V}_{O}}{{V}_{I}} = \frac{1}{2 + sRC} , where s = j ω \qquad Eq . 2$$

FIG. 3 illustrates a graph of the transfer function (Eq. 2). It can be seen that there is less crosstalk at higher frequencies because the single capacitor C_{OUT} acts as an AC ground with improved functionality at higher frequencies. As depicted in FIG. 3, the crosstalk is approximately −6 dB at 20 Hz and decreases to approximately −60 dB at 20 kHz with a 22 ohm load speakers (44 ohms total), which is typical for a set of headphones.

A listener's perception of sound quality and the effect of crosstalk on sound quality is subjective and can be difficult to quantify. There are a number of factors that effect the perception of sound, but one of the more significant ones is the nature of the ear itself. The ear is a nonlinear device and, as a result, tones interact with each other and are not separately perceived. Some of these factors can somewhat reduce the effect of crosstalk.

One such factor is called masking. When listening through headphones, the ear interprets the loudest sounds and masks out the softer sounds. The crosstalk may be perceivable in each separate signal but when both ears are listening, it becomes difficult to distinguish crosstalk due to the ear's natural ability to tune in to the loudest tones. The frequency, or pitch, of a sound also affects the way the ear detects that sound. Eq. 3, depicted below, illustrates the relationship between the frequency and the wavelength of a sound wave, where the velocity of sound in air, c, is approximately 245 m/s, or 1131 ft/s, at normal room temperature, and frequency is in hertz.

c=fλ Eq. 3

From Eq. 3, it can be illustrated that for a low-frequency tone at 400 Hz, the wavelength is about 2.8 feet, which is significantly longer than the distance between a listener's ears. Both ears would therefore perceive the sound at the same time. Since the brain primarily uses any time delay between the perception of a sound by each ear to locate the source of that sound, a listener has difficulty in associating the point of origin of a low-frequency sound. It is this difficulty that allows a woofer or subwoofer to be placed anywhere in a room without a listener being able to perceive the location of the sound source.

Generally, the ear is better at determining the origin of mid-frequency and high-frequency sounds. From Eq. 3, it can be illustrated that for a mid-to-high-frequency tone of 5 kHz, the wavelength is approximately 0.22 feet or about 2.7 inches, which is significantly shorter than the distance between a listener's ears. Thus, the brain is then able to perceive a sound wave arriving at one ear before reaching the other, which allows the listener to deduce the direction of the sound source. It is due to this ability that the small satellite loudspeakers in a surround-sound system are typically pointed toward the listener.

In order for a listener to perceive proper stereo separation, a minimum of −15 dB of crosstalk attenuation is typically required. Thus, as depicted in FIG. 3, stereo separation does not become perceivable by a listener until the mid-range audio frequencies where the attenuation ranges from approximately −20 dB to around −40 dB. At high frequencies, the cross-talk attenuation is on the order of −60 dB. For some inexpensive, low quality headphones, this crosstalk is not noticeable because the inexpensive, low quality headphones fail to reproduce those lower frequencies where crosstalk has an effect. In contrast, the crosstalk can be highly noticeable in better quality headphones. Additionally, many headphones are of lower impedance than the 22 ohms illustrated in FIG. 3 and have a more significant crosstalk effect.

The single capacitor power amplifier, such as in FIG. 2, has one less capacitor, thereby providing a lower parts count, smaller layout area, increased reliability and reduced costs but fails to provide as good a frequency response as typical two capacitor amplifiers.

### SUMMARY OF INVENTION

The following presents a simplified summary of the invention in order to provide a basic understanding of some aspects of the invention. This summary is not an extensive overview of the invention. It is intended neither to identify key or critical elements of the invention nor delineate the scope of the invention. Its sole purpose is to present some concepts of the invention in a simplified form as a prelude to the more detailed description that is presented later.

The present invention relates to systems and methods for reducing crosstalk in power amplifiers driving low impedance loads. A low impedance power amplifier includes a first power amplifier and a second power amplifier. The first power amplifier amplifies a first signal and the second power amplifier amplifies a second signal. A mid-rail component is connected to the first power amplifier and the second power amplifier in order to provide a DC bias for the amplified signals. The first and second differential amplifiers drive a low impedance load (e.g., headphone speakers). A common ground of a low impedance load is connected to a mid-rail component that compensates for mid-rail component variations in the amplified signals therein reducing crosstalk. The low impedance power amplifier is well suited to compact multimedia systems, personal digital audio players, wireless phones, personal digital assistants and the like.

According to an aspect of the invention, a low impedance amplifier system is provided. The system includes a first amplifier, a second amplifier, a mid-rail component, a first load and a second load. The first amplifier amplifies a first signal, and the second amplifier amplifies a second signal. The mid-rail component is connected to the first amplifier and the second amplifier and provides a DC bias to the first amplifier and the second amplifier. The first load is driven by the first amplifier, and the second load is driven by the second amplifier. The second load and the first load share a common ground connected to the mid-rail component.

According to another aspect of the system, a low impedance amplifier system is disclosed. The system includes a first amplifier, a second amplifier and a mid-rail component. The first amplifier amplifies a first signal and modifies its output based on mid-rail component voltage variations. The second amplifier amplifies a second signal and modifies its output based on the mid-rail component voltage variations. The mid-rail component is connected to the first amplifier and the second amplifier and provides the mid-rail component voltage variations to the first amplifier and the second amplifier.

According to yet another aspect of the invention, a method of operating a low impedance amplifier is disclosed. A first signal is applied to inputs of a first differential amplifier, and a second signal is applied to inputs of a second differential amplifier. A first load is driven by the first differential amplifier, and a second load is driven by the second differential amplifier. The first load and the second load share a common ground. Feedback information is provided from the first load and the second load. Driving of the first load and the second load is modified according to the feedback information.

The following description and the annexed drawings set forth certain illustrative aspects of the invention. These aspects are indicative, however, of but a few of the various ways in which the principles of the invention may be employed. Other advantages and novel features of the invention will become apparent from the following detailed description of the invention when considered in conjunction with the drawings.

### BRIEF DESCRIPTION OF THE DRAWINGS

FIG. 1 illustrates a schematic diagram of an audio amplifier having a two-capacitor configuration according to the prior art.

FIG. 2 illustrates a schematic diagram of an audio amplifier having a single capacitor configuration according to the prior art.

FIG. 3 illustrates a graph of the transfer function for the audio amplifier of FIG. 2 according to the prior art.

FIG. 4 illustrates a block diagram of a low impedance amplifier according to an aspect of the invention.

FIG. 5 illustrates a block diagram of an audio system according to another aspect of the invention.

FIG. 6 illustrates a schematic diagram of a low impedance amplifier according to yet another aspect of the invention.

FIG. 7 illustrates a schematic diagram of a low impedance amplifier according to another aspect of the invention.

FIG. 8 illustrates a typical headphone connection according to another aspect of the invention.

FIG. 9 illustrates a graph illustrating crosstalk measurements according to an aspect of the invention.

FIG. 10 illustrates a flow diagram of a method of operating a low impedance amplifier according to an aspect of the invention.

FIG. 11 illustrates a flow diagram of a method of operating a low impedance amplifier according to another aspect of the invention.

### DETAILED DESCRIPTION OF THE INVENTION

The present invention relates to systems and methods for reducing crosstalk in power amplifiers driving low impedance loads. A low impedance power amplifier includes a left differential amplifier and a right differential amplifier. The left differential amplifier amplifies a left signal and the right differential amplifier amplifies a right signal. A mid-rail component is connected to the left differential amplifier and the right differential amplifier in order to provide a DC bias for the amplified signals. The left and right differential amplifiers drive a low impedance load (e.g., headphone speakers). A common ground of a low impedance load is connected to a mid-rail component that compensates for mid-rail component variations in the amplified signals and mitigates crosstalk. The low impedance power amplifier generally has one less capacitor, thereby providing a lower parts count, smaller layout area, increased reliability, reduced costs and a reduction in crosstalk as compared with conventional low impedance power amplifiers. The low impedance power amplifier is well suited for compact multimedia systems, personal digital audio players, wireless phones, personal digital assistants and the like.

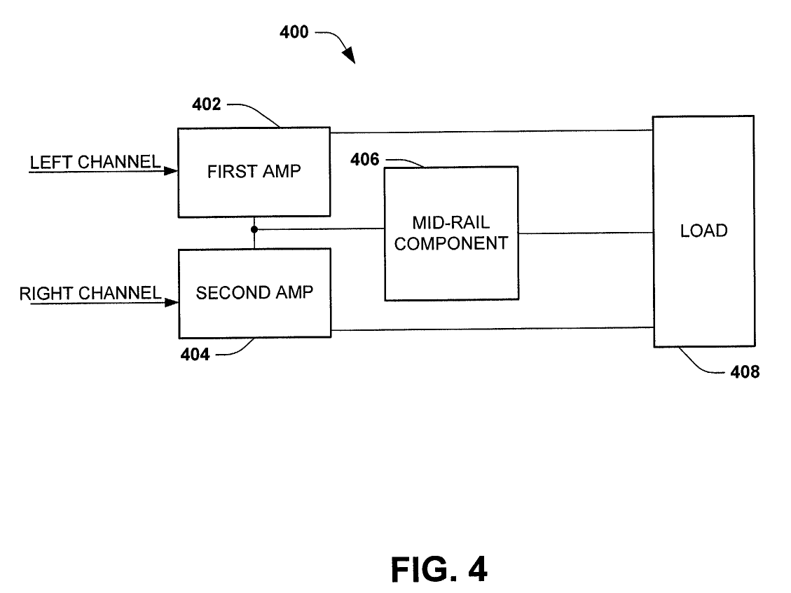

Referring now to FIG. 4, a block diagram is illustrated for a low impedance amplifier 400 according to an aspect of the invention. The low impedance amplifier 400 is operative to drive a low impedance load. The low impedance amplifier 400 is typically a stereo amplifier employed in audio applications. However, it is appreciated that the low impedance amplifier 400 can be used for any suitable application wherein a plurality of signals are amplified and applied to a low impedance load. For example, the low impedance amplifier can be utilized with video and/or image processing. The low impedance amplifier 400 generally has one less capacitor than conventional low impedance power amplifiers, thereby providing a lower parts count, smaller layout area, increased reliability and reduced costs and a reduced amount of crosstalk (particularly at low frequencies) as compared with conventional low impedance power amplifiers.

A first amplifier 402 receives a first signal and amplifies the first signal. The first amplifier can be a differential type amplifier. A second amplifier 404 receives a second signal and amplifies the second signal. The second amplifier 404 can also be a differential type amplifier. The first amplifier 402 and the second amplifier 404 are configurable to provide a selected and/or desired amount of amplification of the first and second signals. A mid-rail component 406 is connected to the first amplifier 402 and the second amplifier 404. The mid-rail component 406 provides a DC bias to the first amplifier 402 and the second amplifier 404, so as to permit the first amplifier 402 and the second amplifier 404 to properly bias respective outputs (amplified signals).

The first amplifier 402 and the second amplifier 404 drive a load 408. The load 408 is typically a low impedance load such as headphones and/or computer speakers. Typically, the load has an impedance in the range of about 4 ohms to about 600 ohms. However, it is appreciated that the load 408 can have other impedances and/or be a high impedance load and still be in accordance with the present invention. A common ground of the load 408 is connected to the mid-rail component 406 so as to compensate for mid-rail component voltage variations, therein reducing crosstalk. The load 408 can be removably connected to the mid-rail component 406, the first amplifier 402 and the second amplifier 404. For example, if the load 408 is headphones, the headphones can be disconnected and reconnected. Additionally, other load(s) can be connected in place of the load 408.

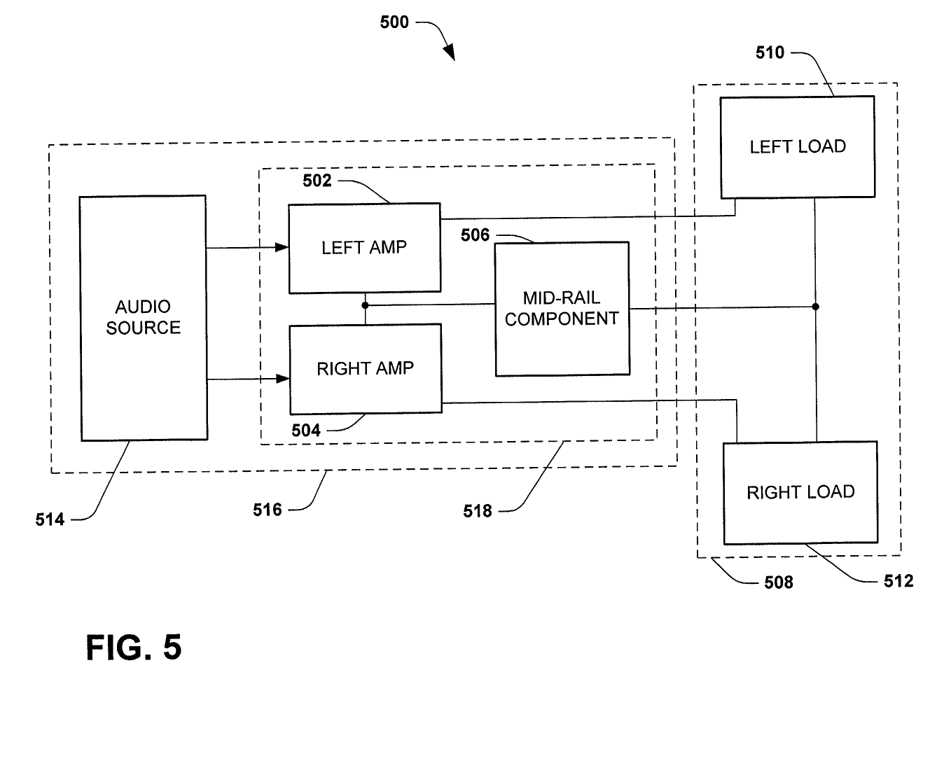

FIG. 5 is a block diagram illustrating an audio system 500 according to another aspect of the invention. The system 500 comprises an audio device 516 and a load 508. The audio device 516 includes an audio source 514 and a low impedance stereo power amplifier 518. The audio source 514 supplies a left signal and a right signal to the low impedance stereo power amplifier 518. The audio source 514 can include audio from one or more of a number of suitable sources such as, but not limited to, digital audio, cassette tape, compact disc (CDDA), MPEG Layer 2 (MP3), radio, satellite radio and the like. Additionally, the audio source 514 is operative to convert digital audio to analog audio prior to supplying the left signal and the right signal.

The low impedance stereo power amplifier 518 includes a left amplifier 502, a right amplifier 504 and a mid-rail component 506. The left amplifier 502 receives the left signal from the audio source 514 and amplifies the left signal. The left amplifier 502 can be a differential type amplifier. The right amplifier 504 receives the right signal from the audio source 514 and amplifies the right signal. The right amplifier 504 can also be a differential type amplifier. The left amplifier 502 and the right amplifier 504 are configurable to provide a selected and/or desired amount of amplification of the left and right signals. A mid-rail component 506 is connected to the left amplifier 502 and the right amplifier 504. The mid-rail component 506 provides a DC bias to the left amplifier 502 and the right amplifier 504 so as to permit the left amplifier 502 and the right amplifier 504 to properly bias their respective outputs (amplified signals).

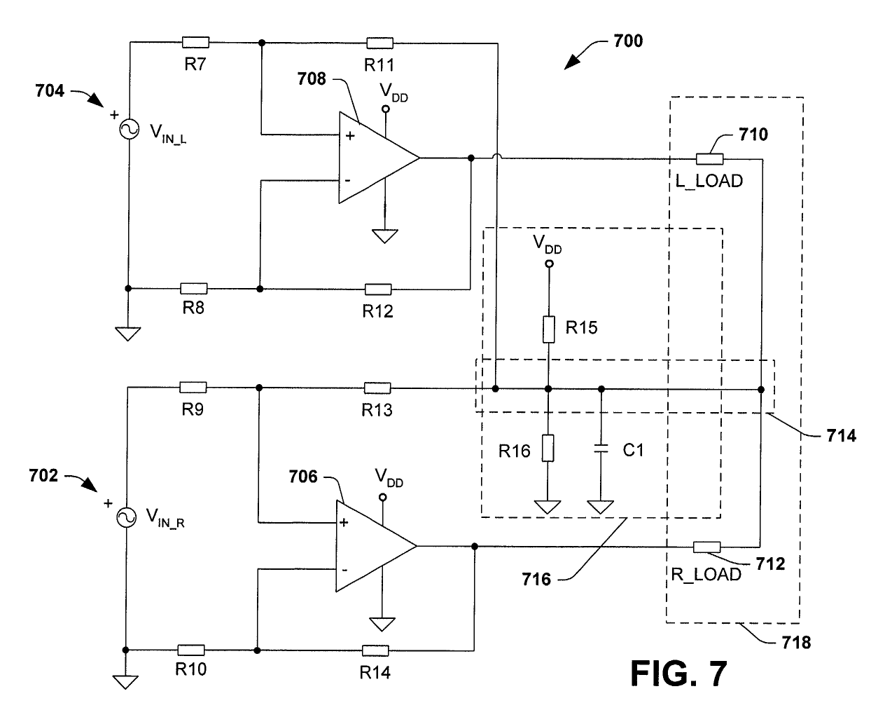

The left amplifier 502 and the right amplifier 504 drive the load 508, which is typically a low impedance load such as headphones and/or computer speakers. Typically, the load has an impedance in the range of about 4 ohms to about 600 ohms. However, it is appreciated that the load 508 can be a high impedance load and still be in accordance with the present invention. A common ground of the load 508 is connected to the mid-rail component 506 so as to compensate for mid-rail component voltage variations, therein reducing crosstalk. The load 508 can be removably connected to the mid-rail component 506, the left amplifier 502 and the right amplifier 504. For example, if the load 508 is headphones, the headphones can be disconnected and reconnected. Additionally, other load(s) can be connected in place of the load 508. The load 508 can be connected to the power amplifier 518 of the audio device 516 via a connection component (not shown) such as, for example a headphone jack as illustrated in FIG. 7.

The load 508 includes a left load 510 and a right load 512. Generally, the left load 510 and the right load 512 are headphone speakers. As can be seen in FIG. 5, a common ground of the left load 510 and the right load 512 are connected to the mid-rail component 506 in order to compensate for mid-rail component voltage variations. Additionally, the left load 510 is connected to the left amplifier 502 and the right load 512 is connected to the right amplifier 504.

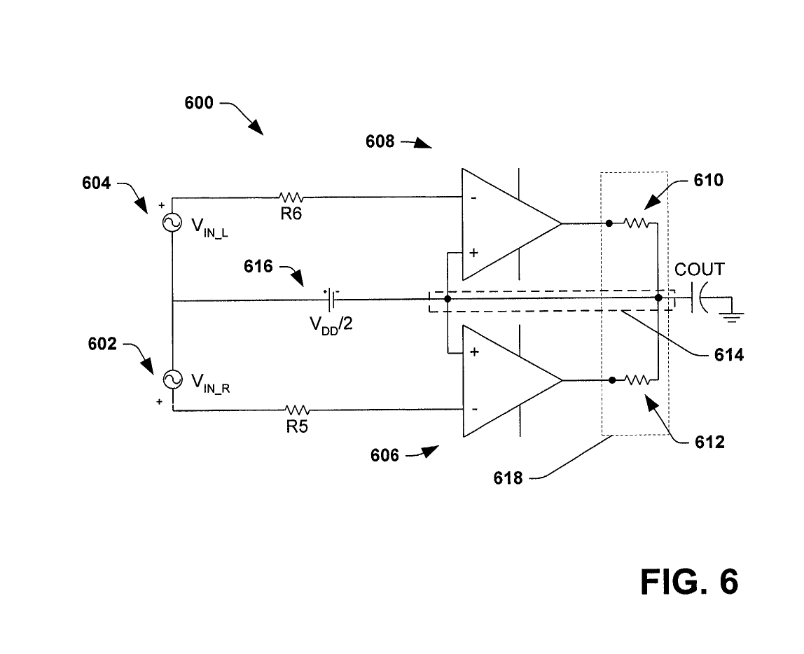

FIG. 6 is a schematic illustrating a low impedance power amplifier 600 according to yet another aspect of the invention. The amplifier 600 is operative to receive a left signal and of an audio signal from a left voltage source 604 and a right signal of an audio signal from a right voltage source 602. The left signal and the right signal are applied to the differential inputs of the left amplifier 608 and the right amplifier 606, respectively. The positive input of the left amplifier 608 and the positive input of the right amplifier 606 are connected to a negative input of a mid-rail component 616, which in turn has its positive input connected to negative terminals of the left voltage source 604 and the right voltage source 602. The mid-rail component 616 provides half of a supply voltage therein providing a DC bias for the left amplifier 608 and the right amplifier 606. A positive terminal of the right voltage source 602 is connected to a negative terminal of the right amplifier 608 via resistor R5. A positive terminal of the left voltage source 604 is connected to a negative terminal of the left amplifier 608 via resistor R6. Some exemplary values that can be used for resistors R5 and R6 are about 10 kilo-ohms.

The left amplifier 608 and the right amplifier 606 are differential amplifiers and are configurable to provide a selected and/or desired amount of amplification. Selectable components (resistors and capacitors) can be connected from the outputs of the amplifiers to the negative terminal (connection not shown) in order to control and/or select the amount of amplification. Additionally, the left amplifier 608 drives a left load 610 and the right amplifier 606 drives a right load 612. The left load 610 and the right load 612 are typically low impedance loads, such as, for example about 4 ohms to about 600 ohms and comprise a load 618. The output of the left amplifier 608 is connected to a first terminal of the left load 610. A second terminal of the left load 610 is connected to a common ground 614 for the left load 610 and the right load 612. Generally, the left load 610 is a left headphone speaker and the right load 612 is a right headphone speaker. The output of the right amplifier 606 is connected to a first terminal of the right load 612. A second terminal of the right load 612 is also connected to the common ground 614. The common ground 614 is connected to a ground, which is the circuit ground or electrical ground, via a capacitor C_{OUT}. The capacitor C_{OUT} is a coupling capacitor and prevents DC offset voltage from reaching the right load 612 and/or the left load 610. Any suitable value can be used for the capacitor C_{OUT}, however, some typical values which can be used are about 33 μF to about 1000 μF. Generally, the higher the capacitance, the less of a limiting frequency effect by the power amplifier 600.

Additionally, the common ground 614 is connected to the negative terminal of the mid-rail component 616, the positive terminal of the left amplifier 608 and the positive terminal of the right amplifier 606. By so doing, the left amplifier 608 and the right amplifier 606 can compensate for variations in a voltage of the mid-rail component 616. The left amplifier 608 and the right amplifier 606 should be differential amplifiers in order to adequately compensate for the variations in the voltage of the mid-rail component 616. This compensation can substantially reduce the effect of crosstalk for the right load 612 and the left load 610, particularly when the right load 612 and the left load 610 are low impedance loads.

FIG. 7 is a schematic illustrating a low impedance power amplifier 700 according to another aspect of the invention. The amplifier 700 is operative to receive a left signal and of an audio signal from a left voltage source 704 and a right signal of an audio signal from a right voltage source 702. The left signal and the right signal are applied to the differential inputs of the left amplifier 708 and the right amplifier 706, respectively. The positive input of the left amplifier 708 and the positive input of the right amplifier 706 are connected to a mid-rail component 716 through resistors R11 and R13, respectively. An exemplary value suitable for the resistors R11 and R13 is about 10 kilo-ohms.

The mid-rail component 716 provides half of a supply voltage therein providing a DC bias for the left amplifier 708 and the right amplifier 706. The mid-rail component 716 comprises resistors R15 and R16 and capacitor C1. A first terminal of the resistor R15 is connected to V_{DD}. A first terminal of the resistor R16 is connected to ground and a second terminal of the resistor R16 is connected to a second terminal of the resistor R15 and a second terminal of the capacitor C1. A first terminal of the capacitor C1 is also connected to ground. The second terminals of R15, R16 and C1 are connected to the positive inputs of the left amplifier 708 and the right amplifier 706 via the resistors R11 and R13, respectively. The second terminals of R15, R16 and C1 provide V_{DD}/2. Additionally, the second terminals of R15, R16 and C1 are connected to a common ground 714. Thus, the capacitor C1 can also act as a coupling capacitor and prevent DC offset voltage from reaching a right load 712 and/or a left load 710 (comprising a load 718), wherein such an offset voltage can damage load 718. An exemplary value for the resistors R15 and R16 is 1 kilo-ohms. An exemplary value for the capacitor C1 is about 47 micro farads.

A positive terminal of the right voltage source 702 is connected to a positive terminal of the right amplifier 706 via resistor R9. A positive terminal of the left voltage source 704 is connected to a positive terminal of the left amplifier 708 via resistor R7. An exemplary value that can be used for resistors R7 and R7 is about 10 kilo-ohms. A negative terminal of the right voltage source 702 is connected to ground and a negative terminal of the right amplifier 706 via resistor R10. A resistor R14 connects the negative terminal of the right amplifier 706 with an output of the right amplifier 706 so as to provide feedback. A negative terminal of the left voltage source 704 is also connected to ground and a negative terminal of the left amplifier 708 via resistor R8. A resistor R12 connects the negative terminal of the left amplifier 708 with an output of the left amplifier 706 so as to provide feedback. An exemplary value for the resistors R7, R8, R9, R10, R12 and R14 is about 10 kilo-ohms.

The left amplifier 708 and the right amplifier 706 are differential amplifiers and are configurable to provide a selected and/or desired amount of amplification. Selectable components (resistors and capacitors) can be connected from the outputs of the amplifiers to the negative terminal (connection not shown) in order to control and/or select the amount of amplification. Additionally, the left amplifier 708 drives the left load 710 and the right amplifier 706 drives the right load 712. The left load 710 and the right load 712 are typically low impedance loads, such as, for example about 4 ohms to about 600 ohms and comprise the load 718. The output of the left amplifier 708 is connected to a first terminal of the left load 710. A second terminal of the left load 710 is connected to the common ground 714 for the left load 710 and the right load 712. Generally, the left load 710 is a left headphone speaker and the right load 712 is a right headphone speaker. The output of the right amplifier 706 is connected to a first terminal of the right load 712. A second terminal of the right load 712 is also connected to the common ground 714. The common ground 714 is connected to a ground, which is the circuit ground or electrical ground, via the capacitor C1. As stated above, the capacitor C1 can also be a coupling capacitor and prevents DC offset voltage from reaching the right load 712 and/or the left load 710. Generally, the higher the capacitance, the less of a limiting frequency effect by the power amplifier 700.

Additionally, as stated above, the common ground 714 is connected to the mid-rail component 716 via the second terminals of R15, R16 and C1. By so doing, the left amplifier 708 and the right amplifier 706 can compensate for variations in a voltage of the mid-rail component 716. The left amplifier 708 and the right amplifier 706 should be differential amplifiers in order to adequately compensate for the variations in the voltage of the mid-rail component 716. This compensation can substantially reduce the effect of crosstalk for the right load 712 and the left load 710, particularly when the right load 712 and the left load 710 are low impedance loads.

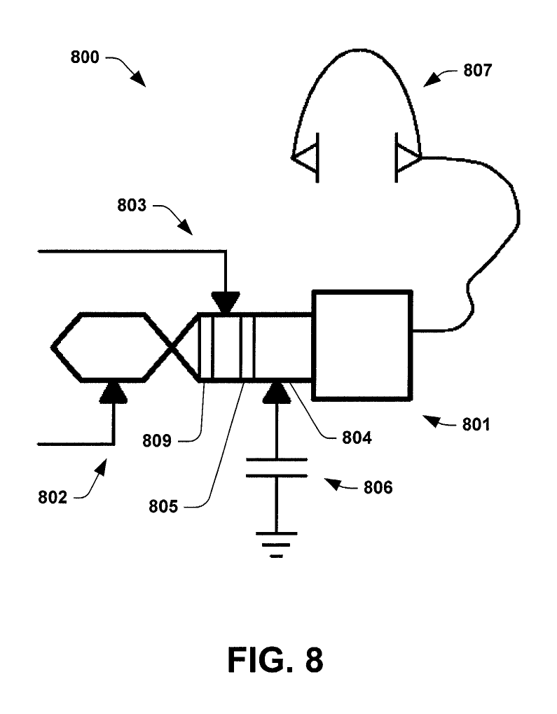

FIG. 8 illustrates a typical connection of a headphone 800 to a low impedance power amplifier (not shown) according to yet another aspect of the invention. The headphone 800 operates as a low impedance load to the low impedance power amplifier. The headphone 800 includes a headphone jack 801, which comprises a left connection 802, a right connection 803 and a common ground connection 804. Isolation regions 805 and 809 electrically isolate the left connection 802, the right connection 803 and the common ground connection 804. The common ground connection 804 is connected to ground (electrical or circuit ground) via a coupling capacitor 806. The coupling capacitor 806 is selected to mitigate DC bias current. The left connection 802, the right connection 803 and the common ground connection 804 provide amplified audio signals to left and right headphone speakers 807. The left and right headphone speakers 807 are generally about 4 ohms to about 84 ohms, respectively. The common ground connection 804 is electrically connected to a mid-rail voltage of the low impedance power amplifier in order to mitigate crosstalk. It is appreciated that other types of connections and loads, such as computer speakers, can be used in accordance with the present invention.

Crosstalk or crosstalk effects can be measured for a low impedance amplifier by driving one speaker (load) with a source and measuring the voltage across a center leg of the circuit. This is equivalent to driving the left or right inputs of an ideal audio amplifier with a sound source and measuring the voltage response across a capacitor attached between two headphone speakers and ground.

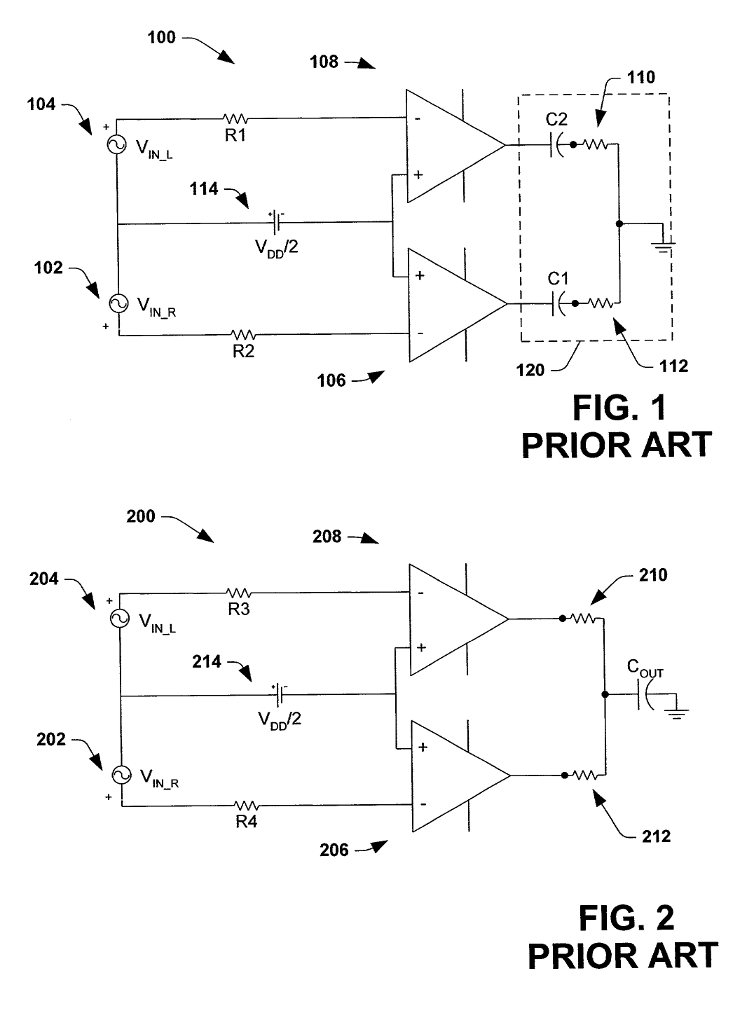

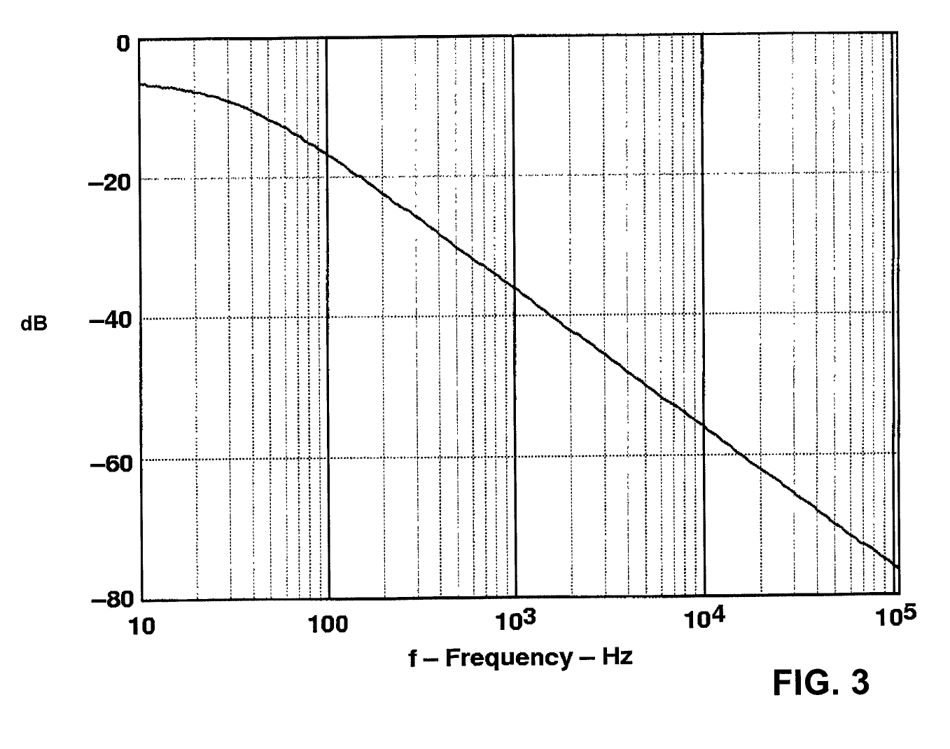

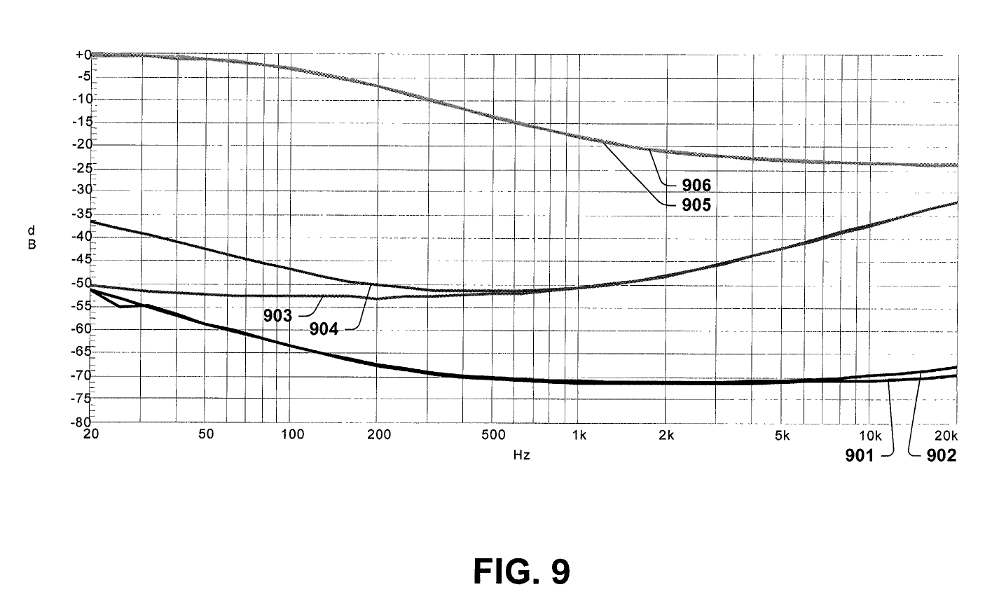

FIG. 9 is a graph illustrating crosstalk measurements (dB) versus frequency (Hz) of amplifiers in accordance with an aspect of the invention. The crosstalk measurements were performed according to the following parameters, a 33 ohm load for each signal (left load and right load), 47 μF coupling capacitors and a 1.063 Vms voltage output. The graph illustrates crosstalk across a typical audio spectrum, 20 Hz-20 kHz. Lines 901 and 902 illustrate crosstalk measurements for a conventional low impedance amplifier employing two coupling capacitors (such as illustrated in FIG. 1). It can be seen from lines 901 and 902 that the crosstalk is sufficiently attenuated (<−15 dB is typically required for a listener to perceive stereo separation). However, as stated above, the conventional low impedance amplifier employing two coupling capacitors requires a higher parts count, greater layout area, decreased reliability and increased costs compared to low impedance amplifiers employing only a single coupling capacitor.

Lines 903 and 904 illustrate crosstalk measurements for a conventional low impedance amplifier employing a single coupling capacitor (such as illustrated in FIG. 2). It can be seen from lines 903 and 904 that the crosstalk does not attenuate to less than −15 dB until after 500 Hz is reached. As such, the conventional low impedance amplifier employing a single coupling capacitor does not provide sufficient crosstalk attenuation for some applications.

Lines 905 and 906 illustrate crosstalk measurements for a low impedance amplifier employing a single coupling capacitor according to an aspect of the present invention (e.g., FIG. 6.). Even at 10 Hz, the crosstalk is sufficiently attenuated (−35 dB to −50 dB). It can be seen from the lines 905 and 906 that the crosstalk is sufficiently attenuated throughout the typical audio spectrum of 20 Hz to 20 KHz. Thus, the low impedance amplifier employing a single coupling capacitor according to an aspect of the present invention provides a lower parts count, smaller layout area, increased reliability and reduced costs and with a reduction of crosstalk interference as compared to conventional methods.

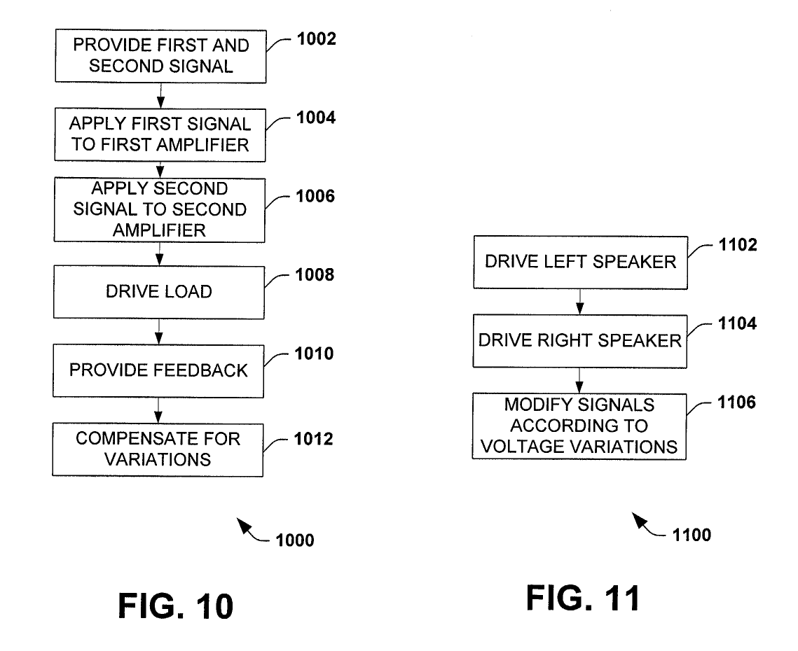

In view of the foregoing structural and functional features described above, a methodology in accordance with various aspects of the present invention will be better appreciated with reference to FIGS. 10-11 . While, for purposes of simplicity of explanation, the methodology of FIGS. 10-11 are depicted and described as executing serially, it is to be understood and appreciated that the present invention is not limited by the illustrated order, as some aspects could, in accordance with the present invention, occur in different orders and/or concurrently with other aspects from that are depicted and described herein. Moreover, not all illustrated features may be required to implement a methodology in accordance with an aspect the present invention.

Thus, referring to FIG. 10, a flow diagram for a method 1000 of operating a low impedance power amplifier according to another aspect of the invention is illustrated. The method is operative to drive a load with a reduction in crosstalk, but with a single coupling capacitor configuration. A first signal and a second signal are provided at 1002. The first signal and the second signal are typically left and right audio input signals. However, it is appreciated that the first and second signal can be other types of signals including, but not limited to, video signals, network signals, multimedia signals, data signals and the like. The first signal is applied to inputs of a first power amplifier at 1004. The second signal is applied to inputs of a second power amplifier at 1006. The first power amplifier and the second power amplifier are generally differential type amplifiers. A load is driven at 1008 by the first power amplifier and the second power amplifier. The load is a low impedance load, typically in the range of about 4 ohms to about 84 ohms. The load can be speakers, such as audio speakers, with separate left and right speakers sharing a common ground. Typically, a coupling capacitor connects the common ground to actual ground or circuit ground. The coupling capacitor prevents the flow of DC current through the load which can damage voice coils in speakers.

Feedback is provided by the load at 1010. The feedback is normally provided by connecting a common ground of the load to a mid-rail component and/or positive inputs of the first power amplifier and the second power amplifier. The feedback indicates variations in the common ground voltage of the load. The first power amplifier and the second power amplifier compensate for mid-rail component voltage variations according to the feedback at 1012, therein facilitating the reduction of crosstalk. Because the feedback indicates variations in voltage, which also correspond to variations in the mid-rail component voltage, the first power amplifier and the second power amplifier are able to compensate for those voltage variations. By compensating for those voltage variations, the first power amplifier can drive a first speaker and the second power amplifier can driver a second speaker without a substantial amount of crosstalk (.i. e., less than −15 dB for about 20 Hz to 20 kHz with a 33 ohm load each for a left and right speaker).

FIG. 11 is a flow diagram of a method 1100 of operating a low impedance power amplifier according to another aspect of the invention. A left speaker is driven by an amplified left signal at 1102. The left speaker typically has a resistance of about 4 ohms to 600 ohms. The left speaker can be a component of a device such as, stereo headphones, computer speakers, surround system speakers and the like. A right speaker is driven by an amplified right signal at 1104. The right speaker typically has a resistance of about 4 ohms to 600 ohms. Similarly, the right speaker can be a component of a device such as, stereo headphones, computer speakers, surround system speakers and the like. Generally, the left speaker and the right speaker are low impedance loads. However, it is appreciated that the left speaker and the right speaker can be higher impedance loads, such as, for example 10 kilo-ohms. The left amplified signal and the right amplified signal are modified at 1106 to adjust for variations in a midrange voltage so as to reduce crosstalk effects. This can be accomplished by, for example, connecting a common ground to a mid-rail component of the low impedance amplifier.

What has been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A low impedance amplifier system comprising:
a first amplifier that amplifies a first signal;
a second amplifier that amplifies a second signal;
a mid-rail component that provides a DC bias to the first amplifier and the second amplifier;
a first load driven by the first amplifier; and
a second load driven by the second amplifier, the second load and the first load sharing a common ground connected to the mid-rail component.

2. The system of claim 1, the first amplifier and the second amplifier being differential type amplifiers.

3. The system of claim 2, the mid-rail component operative to provide half a supply voltage to the first amplifier and the second amplifier.

4. The system of claim 1, the first load and the second load operative to provide feedback to the first amplifier and the second amplifier via the common ground.

5. The system of claim 4, the feedback comprising voltage variations.

6. The system of claim 5, the first amplifier and the second amplifier operative to modify respective outputs according to the voltage variations.

7. The system of claim 1, the first amplifier and the second amplifier having configurable amplification.

8. The system of claim 1, the first load having an impedance of about 4 ohms to about 84 ohms.

9. The system of claim 1, the second load having an impedance of about 4 ohms to about 84 ohms.

10. The system of claim 1, the first load and the second load being speaker components of a stereo headphone.

11. The system of claim 1, the first load being a first computer speaker and the second load being a second computer speaker.

12. The system of claim 1, the first signal and the second signal comprising audio information.

13. The system of claim 1, the low impedance amplifier system being a stereo audio amplifier.

14. A portable digital audio player employing the system of claim 1.

15. A compact disc player employing the system of claim 1.

16. A personal digital assistant employing the system of claim 1.

17. The system of claim 1, further comprising an audio source that generates the first signal and the second signal.

18. The system of claim 17, the audio source being a digital audio source.

19. The system of claim 17, the audio source being an analog audio source.

20. A low impedance amplifier system comprising:
a first amplifier that amplifies a first signal and modifies its output based on mid-rail component voltage variations;
a second amplifier that amplifies a second signal and modifies its output based on the mid-rail component voltage variations; and
a mid-rail component connected to the first amplifier and the second amplifier that provides the mid-rail component voltage variations to the first amplifier and the second amplifier.

21. The system of claim 20, further comprising:
a first load driven by the first amplifier; and
a second load driven by the second amplifier, the second load and the first load that further provide the mid-rail component voltage variations to the first amplifier and the second amplifier.

22. A method of operating a low impedance amplifier comprising:
applying a first signal to inputs of a first differential amplifier;
applying a second signal to inputs of a second differential amplifier;
driving a first load by the first differential amplifier;
driving a second load by the second differential amplifier, the first load and the second load sharing a common ground;
providing feedback information from the first load and the second load;
modifying driving the first load according to the feedback information; and
modifying driving the second load according to the feedback information.

23. The method of claim 22, the feedback information provided identifying mid-rail component voltage variations.

24. The method of claim 22, the driving of the first load and the second load comprising driving stereo headphone speakers.

25. The method of claim 22, further comprising blocking DC bias current from the first load and the second load.

26. A method of operating a low impedance amplifier comprising:
driving a left speaker by a left amplified signal;
driving a right speaker by a right amplified signal; and
modifying the left amplified signal and the right amplified signal according to mid-rail component voltage variations, the mid-rail component voltage variations at least partially comprising feedback from the left speaker and the right speaker.

27. The method of claim 26, further comprising generating the left amplified signal and the right amplified signal via an audio source.

28. A portable audio player employing the method of claim 26.

29. A low impedance amplifier system comprising:
means for applying a first signal to inputs of a first differential amplifier;
means for applying a second signal to inputs of a second differential amplifier;
means for driving a first load by the first differential amplifier;
means for driving a second load by the second differential amplifier, the first load and the second load sharing a common ground;
means for providing feedback information from the first load and the second load;
means for modifying driving the first load according to the feedback information; and
means for modifying driving the second load according to the feedback information.
